(19) United States
(12) Patent Application Publication
(10) Pub. No.: US 2016/0372891 A1
(43) Pub. Date: Dec. 22, 2016

(54) EXTERNAL RESONATOR TYPE LIGHT EMITTING DEVICE

(71) Applicant: NGK INSULATORS, LTD., Nagoya-City (JP)

(72) Inventors: Jungo KONDO, Miyoshi-City (JP); Shoichiro YAMAGUCHI, Ichinomiya-City (JP); Takashi YOSHINO, Ama-City (JP); Yukihisa TAKEUCHI, Nagoya-City (JP)

(73) Assignee: NGK INSULATORS, LTD., Nagoya-City (JP)

(21) Appl. No.: 15/204,102

(22) Filed: Jul. 7, 2016

Related U.S. Application Data
(63) Continuation of application No. PCT/JP2015/050279, filed on Jan. 7, 2015.

(30) Foreign Application Priority Data
Jan. 14, 2014 (JP) 2014-004240

(51) Int. Cl. H01S 5/14; H01S 5/06; H01S 5/028; H01S 5/065

(52) U.S. Cl. CPC H01S 5/141; H01S 5/0654; H01S 5/0612; H01S 5/028

(57) ABSTRACT

A semiconductor light source includes an active layer oscillating a semiconductor laser light. The grating device includes a ridge type optical waveguide comprising an incident face to which said semiconductor laser light is made incident and an emitting face for emitting an emitted light having a desired wavelength, a Bragg grating comprising convexes and concaves and formed in said ridge type optical waveguide, and an emitting side propagating portion disposed between the incident face and said Bragg grating. The system oscillates the laser in a reflection wavelength range of said Bragg grating. A width of the optical waveguide in the Bragg grating and a width of the optical waveguide at the emitting face are different from each other.

### TECHNICAL FIELD

The present invention relates to an external resonator type light emitting system using a grating device.

### BACKGROUND ARTS

Generally, semiconductor lasers having Fabry-Perot (FP) resonator configuration are used, the resonator being formed by mirrors on the both end faces of an active layer. However, the FP lasers produce laser light at a wavelength that satisfies conditions for forming standing waves. Thus, the lasers tend to operate in a multi-longitudinal mode. Particularly as the current and the temperature change, the laser oscillation wavelength varies, which results in a change in optical intensity.

Thus, in applications in optical communication, gas sensing, and the like, there has been a need for a laser that exhibits high wavelength stability and that operates in a single mode. Thus, distributed feed-back (DFB) lasers and distributed reflection (DBR) lasers have been developed. These lasers include a grating in a semiconductor element and produce only laser light having a specific wavelength by using the wavelength dependency of the grating.

Examples of semiconductor lasers that exhibit wavelength stability can include DBR lasers and DFB lasers having a grating that is monolithically formed in the semiconductor laser and external resonator lasers having a fiber grating (FBG) grating disposed on the exterior of the laser. The principle of these lasers is that a part of laser light is returned to the lasers by wavelength-selective mirrors that use Bragg reflection to achieve wavelength stable operation.

DBR lasers include ridges and grooves that are formed in a surface of a waveguide lying on the same straight line as a waveguide in the active layer and mirrors that uses Bragg reflection for realizing a resonator (Patent Document 1 (Japanese Unexamined Patent Application Publication No. S49-128689A) and Patent Document 2 (Japanese Unexamined Patent Application Publication No. S56-148880A)). These lasers include a grating on the both end surfaces of the optical waveguide layer. Thus, light emitted by the active layer is propagated through the optical waveguide layer, and a part of the light is reflected by the grating and is returned to the current injection portion, where the light is amplified. Only light having a single wavelength is reflected by the grating in a predetermined direction, and thus laser light has a constant wavelength.

As an application of such lasers, external resonator semiconductor lasers that include the grating as a separate component from a semiconductor element to form an external resonator have been developed. This type of lasers exhibit good wavelength stability, temperature stability, and controllability. Examples of the external resonator include fiber Bragg gratings (FBG) (Non-Patent Document 1) and volume holographic gratings (VHG) (Non-Patent Document 2). The gratings are configured to be a separate component from the semiconductor lasers, and thus the lasers are characterized in that the reflectance and the resonator length can be independently designed. As the gratings are not affected by temperature rise due to heat generation caused by current injection, the wavelength stability can be further improved. As the semiconductor material has a different temperature dependency of the refractive index, the temperature stability can be improved by designing the refractive index together with the length of the resonator.

Patent Document 6 (Japanese Unexamined Patent Application Publication No. 2002-134833A) discloses an external resonator laser that uses a grating formed in a silica glass waveguide. The patent is to provide a frequency-stable laser that can be used, without a temperature controller, in an environment in which room temperature significantly changes (for example 30° C. or more). The patent describes provision of a temperature-independent laser that prevents mode hopping and that does not depend on temperature for laser oscillation frequency.

Patent Document 8 (Japanese Unexamined Patent Application Publication No. 2010-171252A) discloses an external resonator laser that includes an optical waveguide having a core layer of SiO₂, SiO₁₋ₓNₓ (wherein x is from 0.55 to 0.65), or Si and SiN and a grating formed on the optical waveguide. The external resonator laser maintains a constant laser oscillation wavelength without precise temperature-control and presupposes that a change in reflection wavelength with temperature (temperature coefficient of the Bragg reflection wavelength) of the grating is decreased. Based on this, the patent describes that operation of the laser in a multi-longitudinal mode can provide power stability.

Patent Document 9 (Japanese Patent No. 3667209B) discloses an external resonator laser that uses a grating formed in an optical waveguide of quartz, InP, GaAs, LiNbO₃, LiTaO₃, or polyimide resin. The patent described that the reflectance of the emitting face of the semiconductor laser, which is a light source, is the effective reflectance Rₑ (substantially from 0.1 to 38.4%), and that based on this, operation of the laser in a multi and longitudinal mode can provide power stability.

### RELATED ART DOCUMENTS

### Patent Documents

Patent Document 1: Japanese Unexamined Patent Application Publication No. S49-128689A
Patent Document 2: Japanese Unexamined Patent Application Publication No. S56-148880A
Patent Document 3: WO2013/034813 A1
Patent Document 4: Japanese Unexamined Patent Application Publication No. 2000-082864A
Patent Document 5: Japanese Unexamined Patent Application Publication No. 2006-222399A
Patent Document 6: Japanese Unexamined Patent Application Publication No. 2002-134833A
Patent Document 7: Japanese Patent Application No. 2013-120999
Patent Document 8: Japanese Unexamined Patent Application Publication No. 2010-171252A
Patent Document 9: Japanese Patent No. 3667209B

### Non-Patent Documents

Non-Patent Document 1: IEICE Transactions on Fundamentals of Electronics, Communications and Computer Sciences, C-II, Vol. J81, No. 7, pp. 664-665, July, 1998
Non-Patent Document 2: IEICE Technical Report LQE, 2005, Vol. 105, No. 52, pp. 17-20 Non-Patent Document 3: Furukawa Review, January, 2000, No. 105, p 24-29

### SUMMARY OF THE INVENTION

Non-Patent Document 1 describes the mechanism of mode hopping that impairs wavelength stability due to temperature rise and its remedy.

The wavelength change δλs with temperature of an external resonator laser is represented by the following formula based on standing wave conditions. In the formula, Ana is the refractive index change of the active layer region of the semiconductor, Lₐ is the length of the active layer, Δnf is the refractive index change of the FBG region, Lf is the length of the FBG region, δTa is the temperature change of the active layer region, and δTf is the temperature change of the FBG region.

$${δλ}_{s} = {λ}_{0} \frac{Δ {n}_{a} {L}_{a}}{{n}_{f} {L}_{f} + {n}_{a} {L}_{a}} δ {T}_{a} + {λ}_{0} \frac{Δ {n}_{f} {L}_{f}}{{n}_{f} {L}_{f} + {n}_{a} {L}_{a}} δ {T}_{f} \qquad [ Formula 1 ]$$

In the formula, λ0 represents the reflection wavelength of the grating in the initial state.

The change δλG in reflection wavelength of the grating is represented by the following formula:

$${δλ}_{G} = {λ}_{0} \frac{Δ {n}_{f}}{{n}_{f}} δ {T}_{f} \qquad [ Formula 2 ]$$

A mode hop occurs when the longitudinal mode spacing Δλ of the external resonator is equal to the difference between the wavelength change δλs and the reflection wavelength change δλG of the grating, and thus the following formula is obtained:

$$Δλ = {δλ}_{s} - {λ}_{0} \frac{Δ {n}_{f}}{{n}_{f}} δ {T}_{f} \qquad [ Formula 3 ]$$

The longitudinal mode spacing Δλ is approximately represented by the following formula:

$$Δλ = \frac{{λ}_{0}^{2}}{2 ( {n}_{f} {L}_{f} + {n}_{a} {L}_{a} )} \qquad [ Formula 4 ]$$

From the Formula 3 and the Formula 4, a Formula 5 is obtained.

$$Δ {T}_{all} = \frac{{λ}_{0}}{2 {n}_{a} {L}_{a} ( \frac{Δ {n}_{a}}{{n}_{a}} - \frac{Δ {n}_{f}}{{n}_{f}} )} \qquad [ Formula 5 ]$$

To prevent mode hopping, the laser needs to be used at a temperature of ΔTall or lower, and the temperature is controlled by a Peltier element. In the Formula 5, when the active layer and the grating layer have the same refractive index change (Δna/na=Δnf/nf), the denominator is zero, and the temperature at which a mode hop occurs is infinite, which indicates that any mode hop would not occur. However, in monolithic DBR lasers, current is injected into the active layer for laser oscillation, and thus the active layer and the grating layer cannot have the same refractive index change, which causes mode hopping.

The mode hopping is the phenomenon in which the laser oscillation mode (longitudinal mode) within the resonator is shifted from one mode to another mode. As the temperature or injection current changes, the conditions of the gain and the resonator are changed, and then the laser oscillation wavelength varies, which causes the problem, called kink, that the optical power fluctuates. Thus, in the case of FP GaAs semiconductor lasers, the wavelength normally changes at a temperature coefficient of 0.3 nm/° C., while the wavelength would change more significantly when a mode hope occurs. At the same time, the output changes by 5 percent or more.

Thus, a Peltier device is used to control the temperature in order to prevent mode hopping. However, this increases the number of components, the size of the module, and the cost.

In the Patent Document 6, temperature independence is achieved by applying stress to the optical waveguide layer to compensate for the temperature coefficient due to thermal expansion while the conventional resonator structure is maintained. Thus, a metal plate is adhered onto the element, and a layer for adjusting the temperature coefficient is added into the waveguide. This causes the problem that the size of the resonator structure is further increased.

In the Patent Document 7, the inventors of the present invention disclosed an external resonator laser structure that uses an optical waveguide grating device. In the application, when the full width at half maximum ΔλG of the reflective characteristics of the grating device satisfies a predetermined formula, the structure can produce laser light with good wavelength stability and no power variation, without temperature control.

However, as the inventors have investigated further, the following problems were found. That is, in the case that the ambient temperature is changed and a thermal stress is applied on the grating device, higher mode light may be oscillated between the Bragg grating and emitting face.

An object of the present invention is, in an external resonator type laser utilizing a grating device, to prevent oscillation of a higher mode between a Bragg grating and an emitting face when a thermal stress is applied on the grating device.

An external resonator type light emitting system comprising a semiconductor laser light source and a grating device constituting an external resonator with the semiconductor light source;

wherein said semiconductor laser light source comprises an active layer oscillating a semiconductor laser light;

wherein said grating device comprises a ridge type optical waveguide comprising an incident face to which the semiconductor laser light is made incident and an emitting face for emitting a light having a desired wavelength, a Bragg grating comprising convexes and concaves formed in the ridge type optical waveguide, and an emitting side propagating portion disposed between the Bragg grating and the emitting face,

wherein said system oscillates a laser in a reflection wavelength range of the Bragg grating, and

wherein a width of the optical waveguide in the Bragg grating is different from a width of the optical waveguide at the emitting face.

The inventors have studied the reason that, when a thermal stress is applied on a grating device, a higher mode is excited between a Bragg grating and an emitting face. As a result, it was found that the deformation of near field pattern of a laser becomes significant around the emitting face of the device to result in the excitement of the higher mode and a reduction of a connection efficiency of the emitted light.

That is, for improving the connection efficiency with the semiconductor laser device, the width of the optical waveguide in the Bragg grating is made comparable with the near field pattern of the laser. The size of the near field pattern in horizontal direction of the semiconductor laser may be set at 2 to 7 μm, for example. In this case, the width of the optical waveguide of the grating device is set in a range of 2 m to 7 μm.

However, according to the optical waveguide structure shown in FIG. 3, for example, in the case that the substrate thickness is as thin as 0.5 μm to 3 μm for example, the waveguide is converted to a multi-mode waveguide and the sizes of the near field pattern in the horizontal and vertical directions become different from each other to result in compressed shape.

In the case that the optical waveguide in the Bragg grating is of multi-mode, the fundamental mode and higher mode have different propagation constants, so that Bragg reflection takes place at different wavelengths. However, by adjusting the gain characteristics of the laser and reflection characteristics of the grating, laser oscillation can be selectively realized in reflection wavelength bands in the fundamental mode or in the higher mode. That is, by adjusting the gain curve to the reflection wavelength band of the fundamental mode, it is possible to perform the laser oscillation of the fundamental mode.

However, in this case, it was found that the higher mode is excited between the Bragg grating and emitting face in the case that an ambient temperature is changed and a thermal stress is applied on the grating device.

The distribution of the optical electric field (transverse mode pattern) is disturbed by the convexes and concaves in the grating portion. Conventionally, even in the case that the emitting portion is of multi-mode, the fundamental mode is oscillated. However, as the shrinkage or bending stress is applied on the waveguide portion due to change of the ambient temperature, the higher mode is oscillated to make the waveguide multi-mode. Further, in the case that the reflection at the end face is observed, the same phenomenon would be caused. Such phenomenon is more considerable as the ratio (aspect ratio) of the sizes of the near field pattern in the horizontal and vertical directions is large.

Based on such discovery, the present inventors have changed the width of the optical waveguide at the emitting face with respect to the width of the optical waveguide in the Bragg grating. It could be thereby possible to prevent the deformation of the near field pattern at the emitting face and to prevent the oscillation of the higher mode, and reached the present invention.

### BRIEF DESCRIPTION OF THE DRAWINGS

FIG. 1 is a schematic view of an external resonator type light emitting system.

FIG. 2 is a plan view schematically showing an external resonator type light emitting system 1.

FIG. 3 is a cross-sectional view of a grating device.

FIG. 4 is a perspective view schematically illustrating a grating device.

FIG. 5 is a cross-sectional view of another grating device.

FIG. 6 is a schematic view of an external resonator type light emitting system according to another embodiment.

FIG. 7 illustrates a mode hop according to a conventional example.

FIG. 8 illustrates a mode hop according to a conventional example.

FIG. 9 illustrates an example of a discrete phase condition in a preferred embodiment.

FIG. 10 shows spectrum of a light amount of a light source and spectrum of a system obtained by adding a grating device to the light source.

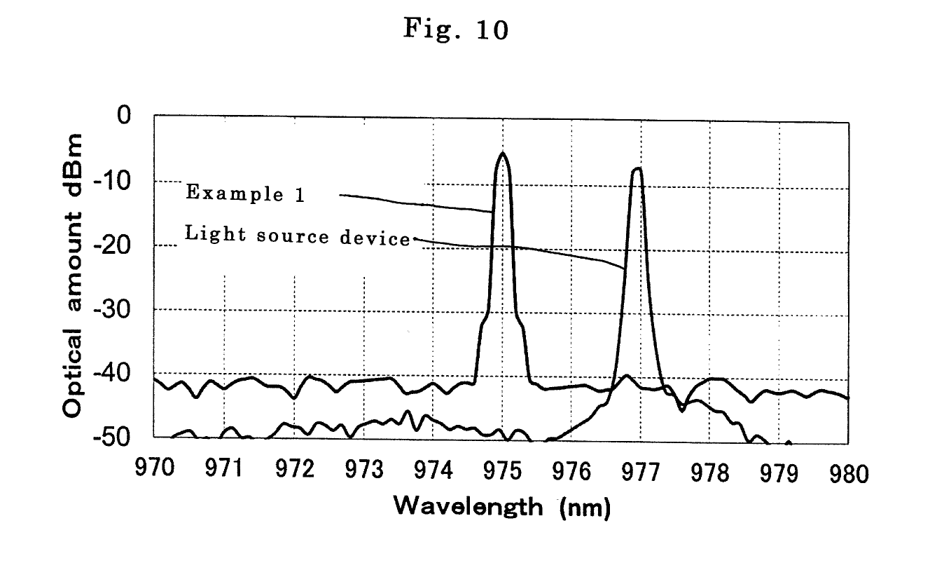

FIG. 11 is a diagram illustrating laser oscillation condition.

FIG. 12 is a cross sectional view showing a still another grating device.

### DESCRIPTION OF THE EMBODIMENTS

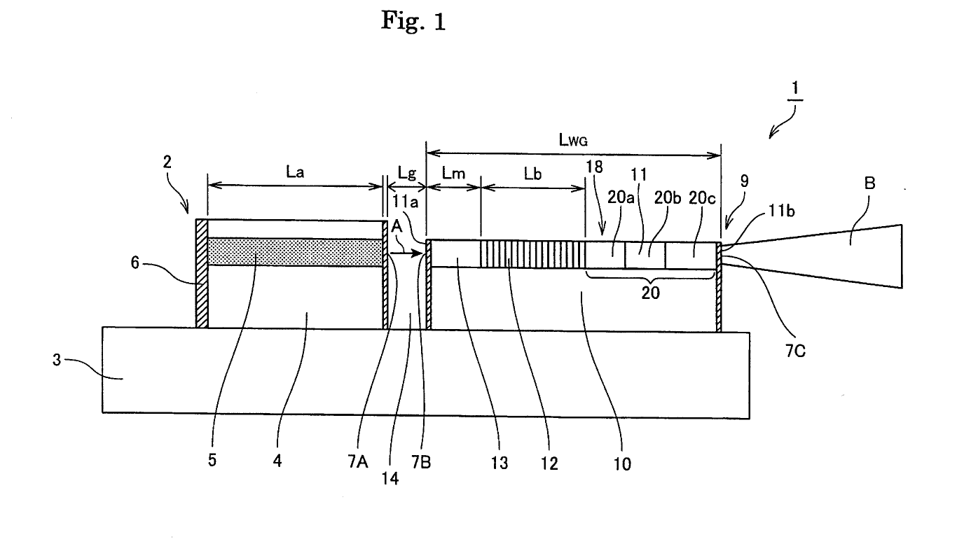

An external resonator type light emitting system 1 schematically illustrated in FIG. 1 includes a light source 2 that emits semiconductor laser light and a grating device 9. The light source 2 and the grating device 9 are mounted on a common substrate 3.

The light source 2 includes an active layer 5 that emits semiconductor laser light. In the embodiment, the active layer 5 is disposed on a substrate 4. A reflective coating 6 is disposed on an outer end face of the substrate 4, and an anti-reflective layer 7A is disposed on the end face of the active layer 5, facing the grating device.

However, the light source 2 may be a light source capable of oscillating a laser by itself. It means that the light source 2 can oscillate laser by itself without a grating device.

The light source 2 preferably oscillates the longitudinal mode in single mode in the case that it oscillates laser by itself. However, in the case of an external-resonator type laser system that uses a grating device, the reflective characteristics can have wavelength dependence. Then, control of the wavelength dependence of the reflective characteristics allows the longitudinal mode of the external resonator type laser to operate in single mode, even if the longitudinal mode of the light source 2 operates in multi-mode. Thus, according to a preferred embodiment, the external resonator type light emitting system of the present invention oscillates the longitude mode in single mode.

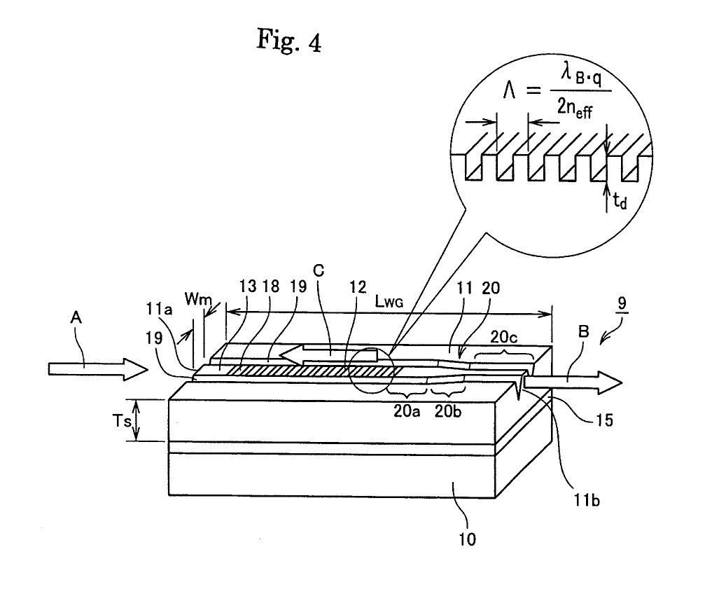

As illustrated in FIG. 1 and FIG. 4, the grating device 9 includes an optical material layer 11 that has an incident face 11a for receiving semiconductor laser light A and an emitting face 11b for emitting light B having a desired wavelength. C is reflected light. A Bragg grating 12 is formed in the optical waveguide 18. A propagating portion 13 having no grating formed therein is disposed between the incident face 11a and the Bragg grating 12 of the optical waveguide 18. The propagating portion 13 is opposed to the active layer 5 via a gap 14. 7B is an anti-reflective coating disposed on the light-receiving side of the optical waveguide 18, and 7C is an anti-reflective coating disposed on the light-emitting side of the optical waveguide 18. The optical waveguide 18 is a ridge optical waveguide and is disposed in the optical material layer 11. The optical waveguide 18 may be formed on the same face as the Bragg grating 12, or may be formed on the opposing face.

The anti-reflective layers 7A, 7B, and 7C need only to have a reflectance that is smaller than the reflectance of the grating and more preferably have a reflectance of 0.1% or less. However, when the end faces have a reflectance that is smaller than the reflectance of the grating, the anti-reflective layers may not be disposed, and a reflective coating may be provided.

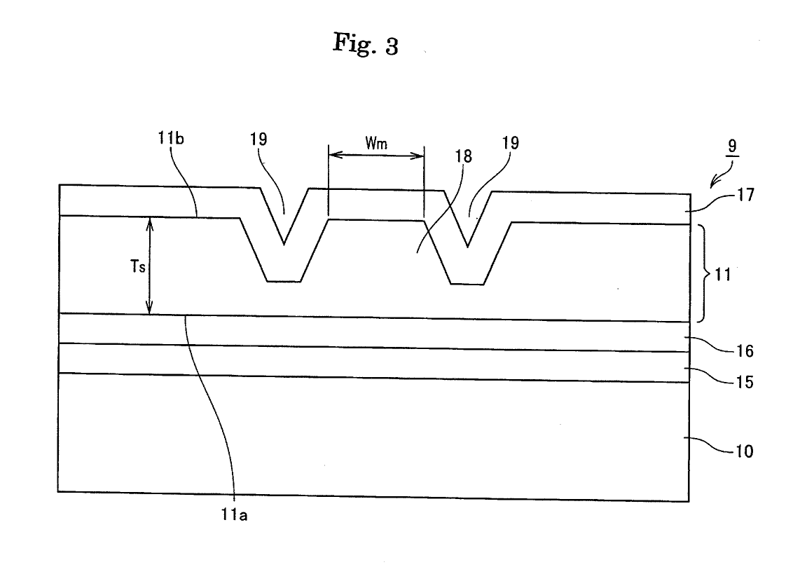

In the embodiment, an adhesive layer 15 is disposed on the substrate 10 as illustrated in FIG. 3. On the adhesive layer 15, the optical material layer 11 is formed via a lower buffer layer 16. On the optical material layer 11, an upper buffer layer 17 is formed. The optical material layer 11 has, for example, a pair of ridge grooves 19 formed therein. The ridge optical waveguide 18 is formed between the ridge grooves. In this case, the Bragg grating may be formed on a flat face 11a or a face 11b. To reduce the variation in the shape of the Bragg grating and the ridge grooves, the Bragg grating and the ridge grooves 19 are preferably disposed on the opposite side from the substrate by forming the Bragg grating on the face 11a.

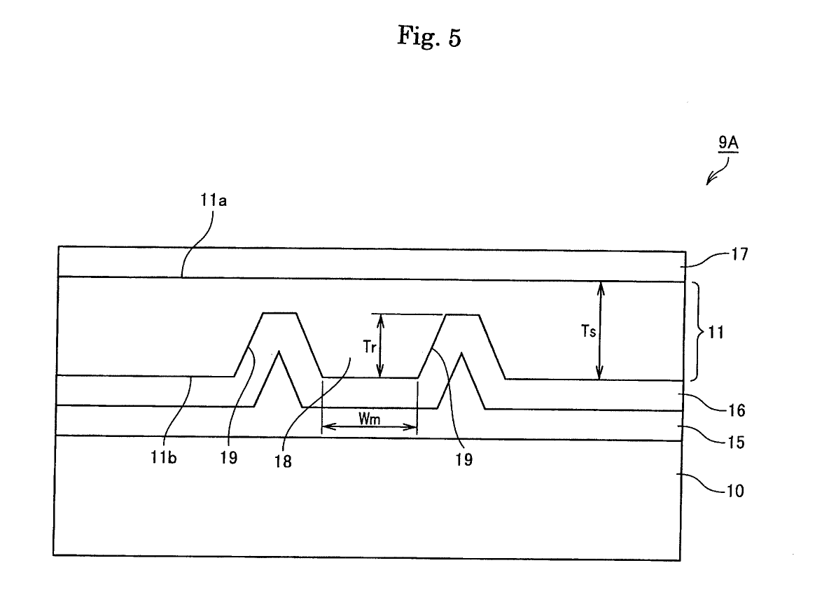

Further, in an element 9A illustrated in FIG. 5, an adhesive layer 15 is disposed on the substrate 10. On the adhesive layer 15, the optical material layer 11 is formed via a lower buffer layer 16. On the optical material layer 11, an upper buffer layer 17 is formed. On a surface of the optical material layer 11, facing the substrate 10, a pair of ridge grooves 19, for example, is formed. A ridge optical waveguide 18 is formed between the ridge grooves 19. In this case, a Bragg grating may be formed on the side of a flat surface 11a or on a surface 11b having the ridge grooves. To reduce the variation in the shape of the Bragg grating and the ridge grooves, the Bragg grating and the ridge grooves 19 are preferably disposed on the opposite side from the substrate by forming the Bragg grating on the side of the flat surface 11a. The upper buffer layer 17 optionally does not exist. In this case, an air layer can be in direct contact with the grating. Thus, provision or omission of the grating grooves can increase the refractive index difference, and a shorter grating length can lead to a higher reflectance.

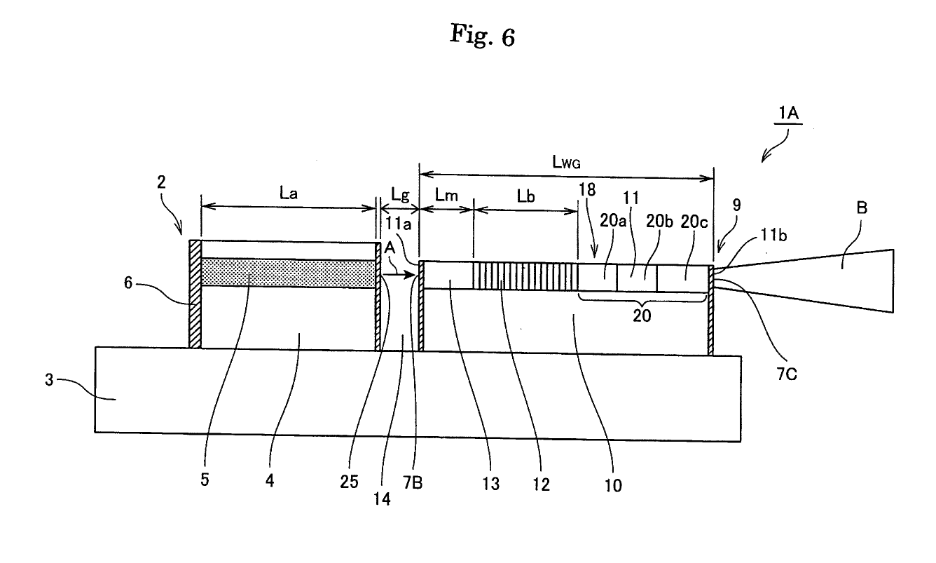

FIG. 6 illustrates a device 1A according to another embodiment. The majority of the device 1A is similar to the device 1 in FIG. 1. A light source 2 includes an active layer 5 that emits laser light, while an anti-reflective layer 7A is not disposed on an end face of the active layer 5, facing a grating device 9, and a reflective coating 25 is formed as an alternative. This is of a type of a conventional semiconductor laser.

The laser oscillation wavelength of the laser light depends on the wavelength of the light reflected by the grating. The laser oscillation condition is satisfied if the light reflected by the grating and the light reflected by the end face of the active layer 5, facing the grating device, have a gain higher than the laser gain threshold. This can provide laser light having high wavelength stability.

The wavelength stability can be further improved by increasing the amount of light reflected by the grating. In view of this, the reflectance of the grating is preferably higher than the reflectance of the end face of the active layer 5. The gain obtained by the resonator with the grating can be thereby made larger than the gain of the original resonator of the semiconductor laser, so that stable oscillation can be realized by the resonator with the grating.

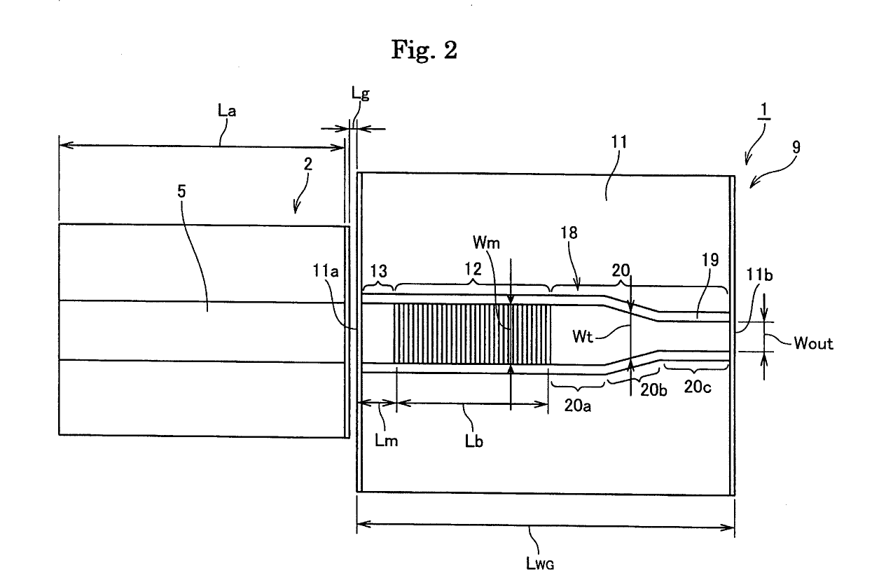

Here, according to the present embodiment, as shown in FIG. 2, an incident-side propagating portion 13 is disposed between the incident face 11a and the Bragg grating 12, and an emitting-side propagating portion 20 is disposed between the emitting face 11b and the Bragg grating 12. According to the present example, the emitting side propagating portion 20 includes a connecting portion 20a continuously formed from an end of the Bragg grating 12, an emitting portion 20c continuously formed from the emitting face 11b of the optical waveguide, and a tapered portion 20b provided between the connecting portion and emitting portion.

According to the present embodiment, the width Wout of the optical waveguide at the emitting face 11b is smaller than the width Wm of the optical waveguide in the Bragg grating 12. Further, the emitting side propagating portion 20 includes a tapered portion 20b in which the width Wt of the optical waveguide is made smaller from the side of the Bragg grating to the emitting face. Besides, according to the present example, the width Wm of the optical waveguide in the connecting portion 20a is constant, and the width Wout of the optical waveguide in the emitting portion is also constant. Further, Wt takes its maximum value Wm at the interface between the tapered portion and connecting portion 20a, and takes its minimum value Wout at the interface between the tapered portion and emitting portion 20c.

Besides, as shown in FIG. 3, the width Wm of the optical waveguide is defined as a width of the narrowest part of the widths in a cross section of the optical waveguide in the cross section along which the ridge portion on forming the optical waveguide is cut. According to the example shown in FIG. 3, the width Wm of the optical waveguide is defined as a distance between the respective edges of an upper face of the ridge portion.

The width Wm of the optical waveguide in the Bragg grating is set at a value comparable with the near field pattern of the laser, for improving the connection efficiency with the semiconductor laser device 2. The size of the near field of the semiconductor laser in horizontal direction may be 2 μm to 7 μm, for example. In this case, the width Wm of the optical waveguide is set at 2 μm to 7 μm.

In the case that the optical waveguide is of multi-mode in the Bragg grating, as the fundamental mode and higher mode have different propagation constants, so that the Bragg reflection takes place at different frequencies. However, by adjusting the gain curve in a reflection wavelength band of the fundamental mode, it is possible to perform the laser oscillation at the fundamental mode. However, in this case, it was proved that, as the ambient temperature is changed and a thermal stress is applied on the grating device 9, higher mode is excited in the emitting side propagating portion between the Bragg grating 12 and emitting face 11b. This phenomenon is more considerable as the ratio (aspect ratio) of the sizes of the near field in horizontal and vertical directions is larger.

Here, according to the present embodiment, since the width Wout of the optical waveguide at the emitting face is made smaller than Wm, it is possible to prevent the increase of the aspect ratio of the near field pattern at the emitting face and thereby to prevent the oscillation of the higher mode.

As the light source, highly reliable GaAs-based or InP-based laser is suitable. When, for example, a nonlinear optical element is used to emit green laser by second harmonic generation in an application of the present structure, GaAs-based laser, which emits light having a wavelength of about 1064 nm, is used. GaAs-based laser and InP-base laser are highly reliable, and thus a light source arranged in a one-dimensional array such as a laser array is also contemplable.

A longer wavelength of the laser from the light source leads to a larger variation of Bragg wavelength with temperature, and thus the light source particularly preferably emits light having an oscillation wavelength of 990 nm or less to improve the wavelength stability. In contrast, an excessively short wavelength of the laser from the light source leads to an excessively large refractive index change Ana of the semiconductor material, thus the light source particularly preferably emits light having an oscillation wavelength of 780 nm or more to improve the wavelength stability.

Further, the material and wavelength of the active layer may be appropriately selected. Further, the light source may be a superluminescent diode or a semiconductor optical amplifier (SOA). Further, the material and wavelength of the active layer may be appropriately selected.

A method for stabilizing power by combination of a semiconductor laser and a grating device is disclosed in the following literature:

(Non-Patent Document 3: Furukawa Review, January, 2000, vols. 105, p 24-29)

The ridge optical waveguide can be obtained by physical machining by, for example, cutting with a peripheral blade or laser ablation and shape-forming.

A Bragg grating can be formed by the following physical or chemical etching.

In particular, a layer of metal such as Ni or Ti is deposited on a high refractive index substrate, and windows are regularly formed by photolithography to form an etch mask. Then, periodical grating grooves are formed using a device for dry etching such as reactive ion etching. Finally, the metal mask can be removed to form the Bragg grating.

To further improve the optical damage resistance of the optical waveguide, one or more metal elements selected from the group consisting of magnesium (Mg), zinc (Zn), scandium (Sc), and indium (In) may be included in the high refractive index layer. In this case, magnesium is particularly preferred. As a doping material, a rare earth element can be included in the crystal. The rare earth element is particularly preferably Nd, Er, Tm, Ho, Dy, or Pr.

The material for the adhesive layer may be an inorganic adhesive, an organic adhesive, or a combination of the inorganic adhesive and the organic adhesive.

The optical material layer 11 may be formed by deposition on the support substrate by a thin film deposition process. Examples of the thin film deposition process can include sputtering, vapor deposition, and CVD. In this case, the optical material layer 11 is directly formed on the support substrate, and the adhesive layer described above does not exist.

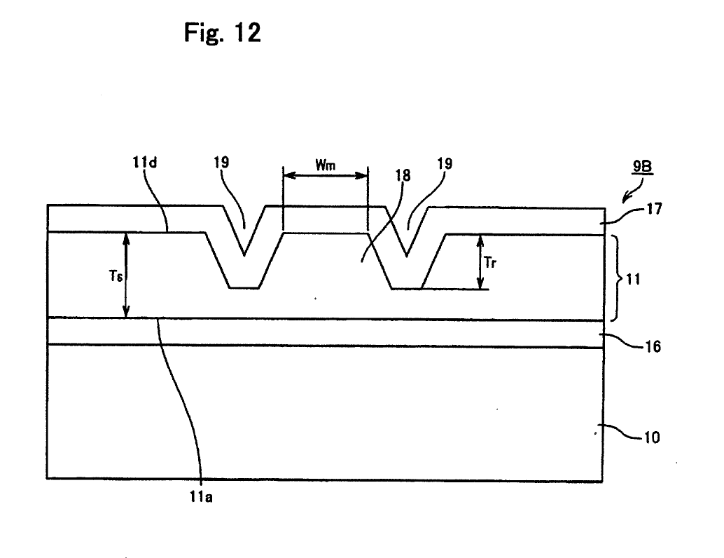

In this case, as a device 9B shown in FIG. 12, the upper buffer layer 16 may be directly formed on a supporting substrate 10 by a thin film forming process without providing the adhesive layer, and the optical material layer 11 may be then formed by a thin film forming process.

The specific material of the support substrate is not restricted, and the example can include lithium niobate, lithium tantalate, glass such as silica glass and quartz, Si.

The reflectance of the anti-reflective layer needs to be equal to or lower than the reflectance of the grating, and the laminate deposited to form the anti-reflective layer may be a laminate film of oxide such as silicon dioxide, tantalum pentoxide, magnesium fluoride, calcium fluoride or the like, or a metal film.

Each of the end faces of the light source element and the grating device may be beveled to reduce reflection on the end faces. The grating device and the support substrate are adhesively bonded together in the example in FIG. 3 and may be directly bonded together.

On the viewpoint of making the propagating light on the emitting side single mode, the width Wout of the optical waveguide at the emitting face may preferably be 4 μm or smaller. Further, on the viewpoint of preventing the flattening of the near field pattern, the width Wout of the optical waveguide at the emitting face may more preferably be 3 μm or smaller and most preferably be 2 μm or smaller.

On the other hand, on the viewpoint of preventing the reduction of propagation coefficient of light in the emitting side propagating portion, the width Wout of the optical waveguide at the emitting face may preferably be 0.1 μm or larger and more preferably be 0.5 μm or larger.

Further, on the viewpoint of connection with the semiconductor laser, the width Wm of the optical waveguide in the Bragg grating may preferably be 2 μm or larger and more preferably be 2.5 μm or larger. Further, on the similar viewpoint, the width Wm of the optical waveguide in the Bragg grating may preferably be 7 μm or smaller and more preferably be 6.5 μm or smaller.

On the viewpoint of the effects of the present invention, the ratio Wout/Wm of the Wout to Wm may preferably be 1/50 or larger and more preferably be 1/10 or larger. Further, it may preferably be 2/3 or smaller and more preferably be 1/2 or smaller.

Further, according to the embodiments described above, the tapered portion 20b, connecting portion 20a having a constant thickness and emitting portion having a constant thickness are provided in the emitting side propagating portion 20. However, the emitting side propagating portion 20 may be composed of a combination of the tapered portion 20b and the connecting portion 20a having a constant thickness, and in this case, the emitting face is positioned at the emitting-side end of the tapered portion 20b. Alternatively, the emitting side propagating portion 20 may be composed of a combination of the tapered portion 20b and the emitting portion 20c having a constant thickness, and in this case, the end on the emitting side of the Bragg grating 12 is continuous with the incident side end of the tapered portion 20b.

Preferred embodiments of the inventive system will be described further below.

As to a grating device, generally in the case that a fiber grating is used, quartz has a small temperature coefficient of a refractive index and thus has a small dλ_{G}/dT and a large|dλ_{G}/dT−dλ_{TM}/dT|. The temperature range in which the mode hopping takes place thus tends to be smaller.

Thus, according to a preferred embodiment, it is used a material having a refractive index of 1.8 or higher for the waveguide substrate with the grating formed therein. It is thereby possible to increase the temperature coefficient of the refractive index and dλ_{G}/dT. |dλ_{G}/dT−dλ_{TM}/dT| can be thus made smaller to increase the temperature range ΔT in which the mode hopping takes place.

Then, according to a preferred embodiment, the above described matters are satisfied and then, contrary to technical prejudice of skilled artisans, the full width at half maximum Δλ_{G} at the peak of the Bragg reflectance is set at a large value. Then, for reducing the likeliness of the mode hopping, it is necessary to set the spacing of the wavelengths satisfying the phase condition (longitudinal mode spacing) at a large value. It is thus needed to shorten the resonator length, so that the length L_{b} of the Bragg grating is made as short as 300 μm or shorter.

Moreover, the depth td of the convexes and concaves forming the Bragg grating is adjusted in a range of 20 nm or larger and 250 nm or smaller so that Δλ_{G} can be controlled in a range from 0.8 nm to 6 nm and the number of the longitudinal modes in the Δλ_{G} can be adjusted at 2 to 5. That is, the wavelengths satisfying the phase condition is discrete, and in the case that the number of the longitudinal modes in Δλ_{G} is 2 or more and 5 or less, the mode hoping takes place in Δλ_{G} and do not take place outside of Δλ_{G}. Substantially large mode hopping can thereby be prevented so that it is possible to improve the stability of wavelength and to prevent the deviation of optical power.

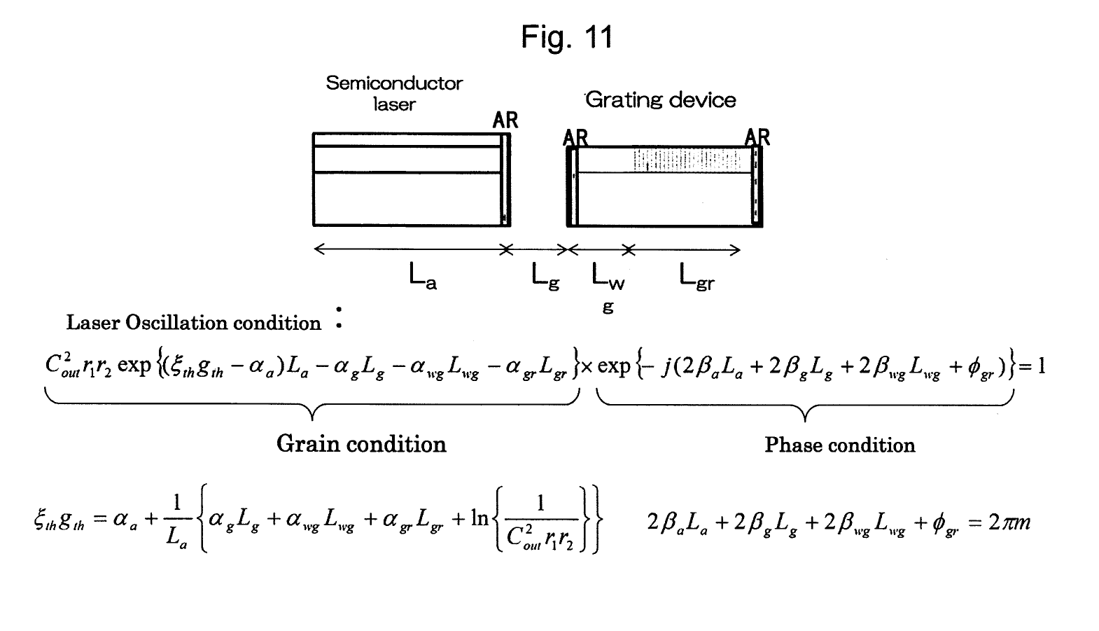

Now, the conditions of the present invention will be further described, in a construction shown in FIG. 11.

However, mathematical formulas are abstract and are difficult to understand, and thus first, an embodiment of the present invention is simply compared with a typical mode of the conventional art to describe the characteristic of the present invention. Then, various conditions of the present invention will be described.

First, the laser oscillation condition of a semiconductor laser is determined by the gain condition and the phase condition as represented by the following formula:

(Cₒᵤₜ²)⁴|r₁∥r₂|exp{(ζₜgₜₕ−αₐ)Lₐ−αₐL_{b}}×exp{j(−α₁−φ₂−2βLₐ)}=1 (2-1)

The gain condition is represented by the following formula derived from the Formula (2-1):

$${ζ}_{t} {g}_{th} = {α}_{a} {L}_{a} + {α}_{b} {L}_{b} + \frac{1}{{L}_{a}} ln ( \frac{1}{\vert {r}_{1} \vert \vert {r}_{2} \vert {C}_{out}^{2}} ) \qquad Formula ( 2 \text{-} 2 )$$

In the formulas, αa, αg, αwg, αd, αgr are the loss coefficient in the active layer, the gap between the semiconductor laser and the waveguide, the waveguide portion on the input side without any grating, and the grating portion, respectively. La, Lg, Lwg, and Lgr are the lengths of the active layer, the gap between the semiconductor laser and the waveguide, the waveguide portion on the input side without any grating, and the grating portion, respectively. r1 and r2 are mirror reflectances (r2 is the reflectance of the grating). Cout is a coupling loss between the grating device and the light source. ξₜgₜₕ is the gain threshold of the laser oscillation medium. φ1 is a phase change on a reflective mirror on the laser side, and φ2 is a phase change on the grating portion.

The Formula (2-2) indicates that when the gain ξₜgₜₕ (gain threshold) of the laser oscillation medium is larger than the loss, the laser oscillates laser light. The gain curve (wavelength dependence) of the laser oscillation medium has a full width at half maximum of 50 nm or more, which is broad. Most of the loss terms (on the right side) are nearly independent on wavelength except for the reflectance of the grating, and thus the gain condition depends on the grating. Thus, for comparison, the gain condition can be considered from only the grating.

The phase condition is represented by the following formula derived from the Formula (2-1). It is noted that φ1 is 0.

φ₂+2βLₐ=2pπ (p represents an integer) Formula (2-3)

When the light source 2 oscillates laser light, the source is a composite resonator. Thus, the above Formulas (2-1), (2-2), and (2-3) become complex and can be considered as indications of laser oscillation.

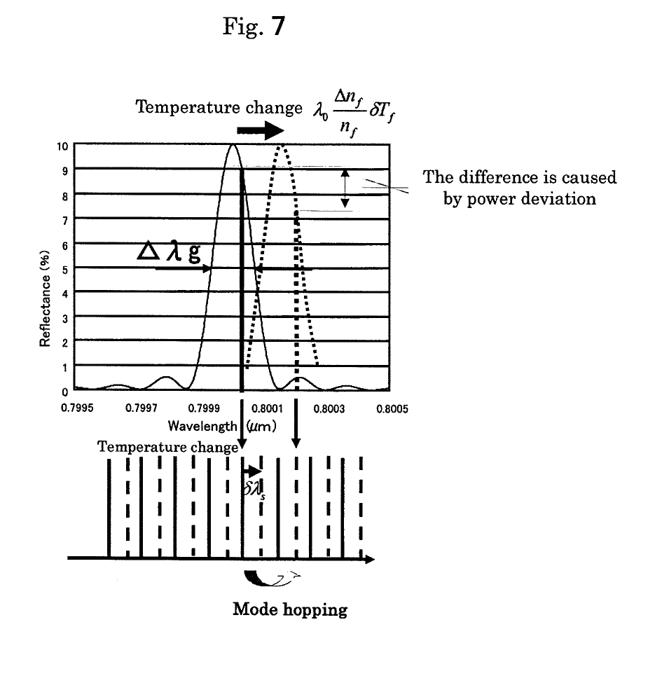

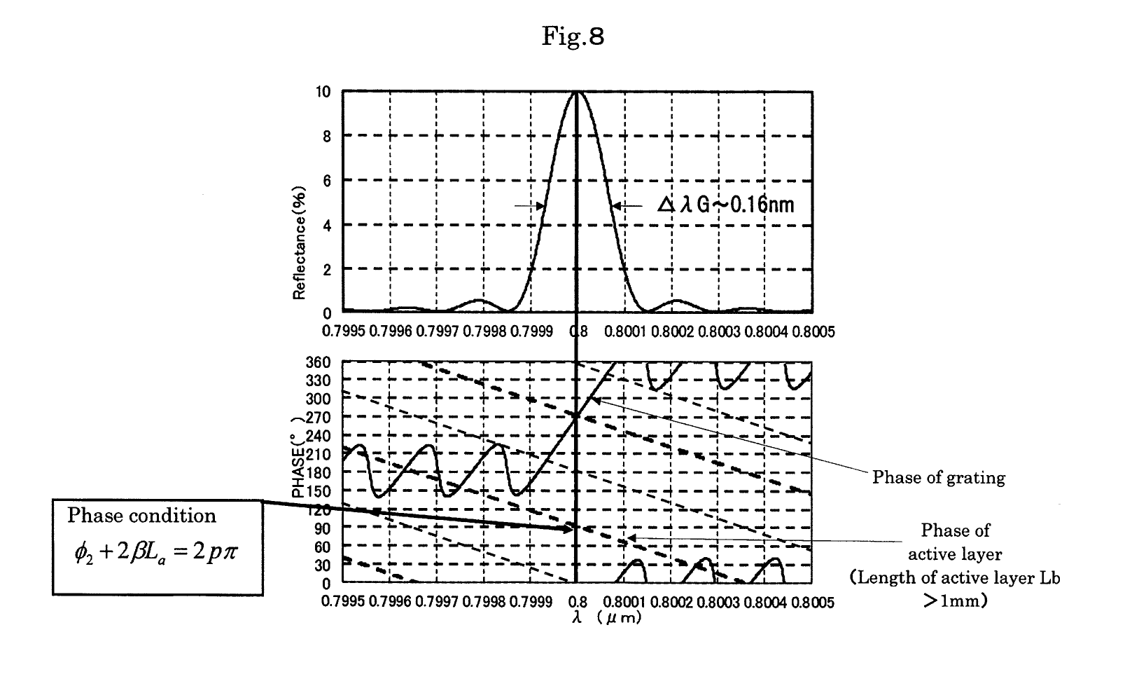

External-resonator type lasers that use a quartz glass optical waveguide or FBG as an external resonator have been commercialized. In a prior design concept, as illustrated in FIG. 7 and FIG. 8, the reflective characteristics of the grating are Δλ_{G} of about 0.2 nm and a reflectance of 10%. Thus, the grating portion has a length of 1 mm. With regard to the phase condition, the wavelengths satisfying the condition are discrete, and the device is designed so that the Formula (2-3) is satisfied at two or three points within Δλ_{G}. Thus, the active layer of the laser oscillation medium needs to have a long length, and the active layer having a length of 1 mm or more is used.

In the case of a glass waveguide or FBG, λg has a very low dependence on temperature, and dλ_{G}/dT is about 0.01 nm/° C. As a result, the external resonator type laser has a characteristic of high wavelength stability.

In contrast, however, the wavelengths satisfying the phase condition have a high dependence on temperature, and dλs/dT and dλ_{TM}/dT are both equal to 0.05 nm/° C. Thus, the difference is 0.04 nm/° C.

Generally, the temperature Tₘₕ at which a mode hop occurs can be represented by the following formula according to Non-Patent Document 1 (Ta is assumed to be equal to Tf.).

ΔG_{TM} is the wavelength spacing (longitudinal mode spacing) satisfying the phase condition of the external resonator type laser.

$${T}_{mh} = \frac{Δ {G}_{TM}}{\vert \frac{d {λ}_{G}}{d T} - \frac{d {λ}_{TM}}{d T} \vert} \qquad Formula ( 2 \text{-} 4 )$$

Thus, in the conventional case, Tₘₕ is about 5° C., at which a mode hop is likely to occur. Thus, when a mode hop occurs, the power is changed by about 5% or more based on the reflective characteristics of the grating.

Because of this, external resonator type lasers that use a conventional glass waveguide or FBG use a Peltier element in operation to control the temperature.

In contrast, the present embodiment presupposes use of a grating device that decreases the denominator of the Formula (2-4). The denominator of the Formula (2-4) is preferably 0.03 nm/° C. or less. Preferred specific examples of the material of the optical material layer include gallium arsenide (GaAs), lithium niobate (LN), tantalum oxide (Ta₂O₅), zinc oxide (ZnO), and aluminum oxide (Al₂O₃).

Further, as the buffer layer, it is preferable a material having a refractive index lower than that of the optical material layer and of transparent and a low loss at wavelengths for use. It may be a material of the same material series as the optical material and whose composition is changed, and the difference of the refractive index from that of the optical material may preferably be larger. On this viewpoint, an oxide such as silicon oxide (SiO₂), aluminum oxide (Al₂O₃) or the like is preferred and an organic material may be also used.

As long as five or less wavelengths that satisfy the phase condition are present within Δλ_{G}, external resonator type lasers can operate in a stable laser oscillation condition even when a mode hop occurs.

In particular, when, for example, polarized light along the Z-axis of lithium niobate is used, the structure of the present embodiment exhibits a laser oscillation wavelength that changes at 0.1 nm/° C. as the temperature changes, depending on the temperature characteristics of the grating, but the power can be less likely to change even when a mode hop occurs. The structure of the present application has a grating length Lb of, for example, 100 μm in order to increase Δλ_{G} and has a length La of, for example, 250 μm in order to increase ΔG_{TM}.

The difference from Patent Document 6 will be also described.

The present application presupposes that the temperature coefficient of the grating wavelength is adjusted close to the temperature coefficient of the gain curve of the semiconductor material. Thus, a material having a refractive index of 1.8 or more is used. Additionally, the grating has a groove depth td of 20 nm or more and 250 nm or less, a reflectance of 3% or more and 60% or less, and a full width at half maximum Δλ_{G} of 0.8 nm or more and 250 nm or less. These can provide a compact resonator structure and eliminate additional components, which can achieve temperature independence. In the Patent Document 6, the respective parameters are described as follows, any of which are within the scope of the conventional art.

Δλ_{G}=0.4 nm

Vertical mode spacing ΔG_{TM}=0.2 nm

Grating length Lb=3 mm

Length of LD active layer La=600 μm

Length of propagating portion=1.5 mm

Now, the following various conditions will be described more specifically.

0.8 nm≦Δλ_{G}≦6.0 nm (1)

10 μm≦L_{b}≦300 μm (2)

20 nm≦td≦250 nm (3)

n_{b}≧1.8 (4)

In the Formula (4), the material that constitutes the Bragg grating has a refractive index n_{b} of 1.8 or more.

Although conventionally, a material, such as silica, having a lower refractive index is generally used, a material having a high refractive index constitutes the Bragg grating in the concept of the present invention. The reason is that a material having a high refractive index exhibits a large change in refractive index with temperature and can increase Tₘₕ in the Formula (2-4) and the temperature coefficient dλ_{G}/dT of the grating as described above. In view of this, n_{b} is more preferably 1.9 or more. Although the upper limit of n_{b} is not critical, the upper limit is 4 or less and more preferably 3.6 or less, otherwise the grating would have a very small pitch, which makes it difficult to form the grating. For the same reason, the optical waveguide preferably has an equivalent refractive index of 3.3 or less.

The full width at half maximum ΔλG of the peak Bragg reflectance is 0.8 nm or more (Formula 1). λ_{G} is a Bragg wavelength. In particular, as illustrated in FIG. 7 and FIG. 8, when the reflection wavelength of the Bragg grating is taken along the abscissa, and the reflectance is taken along the ordinate, then the Bragg wavelength refers to a wavelength at which the maximum reflectance is obtained. The full width at half maximum Δλ_{G} refers to the distance between two wavelengths at which the reflectance is one-half of the peak reflectance at the Bragg wavelength.

The full width at half maximum Δλ_{G} of the peak Bragg reflectance is 0.8 nm or more (Formula (1)). The purpose is to broaden the peak reflectance. In view of this, the full width at half maximum ΔλG is preferably 1.2 nm or more and more preferably 1.5 nm or more. The full width at half maximum Δλ_{G} is 5 nm or less, more preferably 3 nm or less, and still more preferably be 2 nm or less.

The Bragg grating has a length L_{b} of 300 μm or less (Formula 2). The length L_{b} of the Bragg grating refers to the length of the grating along the optical axis of the light propagated through the optical waveguide. The design concept of the present invention presupposes that the Bragg grating has a length L_{b} of 300 μm or less, which is shorter than before. Thus, to make the laser less susceptible to mode hops, it is necessary to widen the wavelength spacing (longitudinal mode spacing) satisfying the phase condition. To achieve this, it is necessary to decrease the length of the resonator, and thus the length of the grating device is decreased. In view of this, the Bragg grating more preferably has a length L_{b} of 200 μm or less.

Decrease of the length of the grating device results in decreased loss, which can reduce the laser oscillation threshold. This allows for operation at low current, with low heat generation, and with low energy.

The grating preferably has a length L_{b} of 5 μm or more to achieve a reflectance of 3% or more and more preferably has a length L_{b} of 10 μm or more to achieve a reflectance of 5% or more.

In the Formula (3), td refers to the depth of the convexes and concaves that constitute the Bragg grating. Satisfaction of 20 nm≦td≦250 nm can achieve Δλ_{G} of 0.8 nm or more and 250 nm or less, and the number of the longitudinal modes within Δλ_{G} can be adjusted to 2 or more and 5 or less. In view of this, td is more preferably 30 nm or more and still more preferably 200 nm or less. To achieve a full width at half maximum of 3 nm or less, td is preferably 150 nm or less.

In a suitable embodiment, the reflectance of the grating device is preferably set at 3% or more and 40% or less to promote laser oscillation. The reflectance is more preferably 5% or more to further stabilize the output power and is more preferably 25% or less to increase the output power.

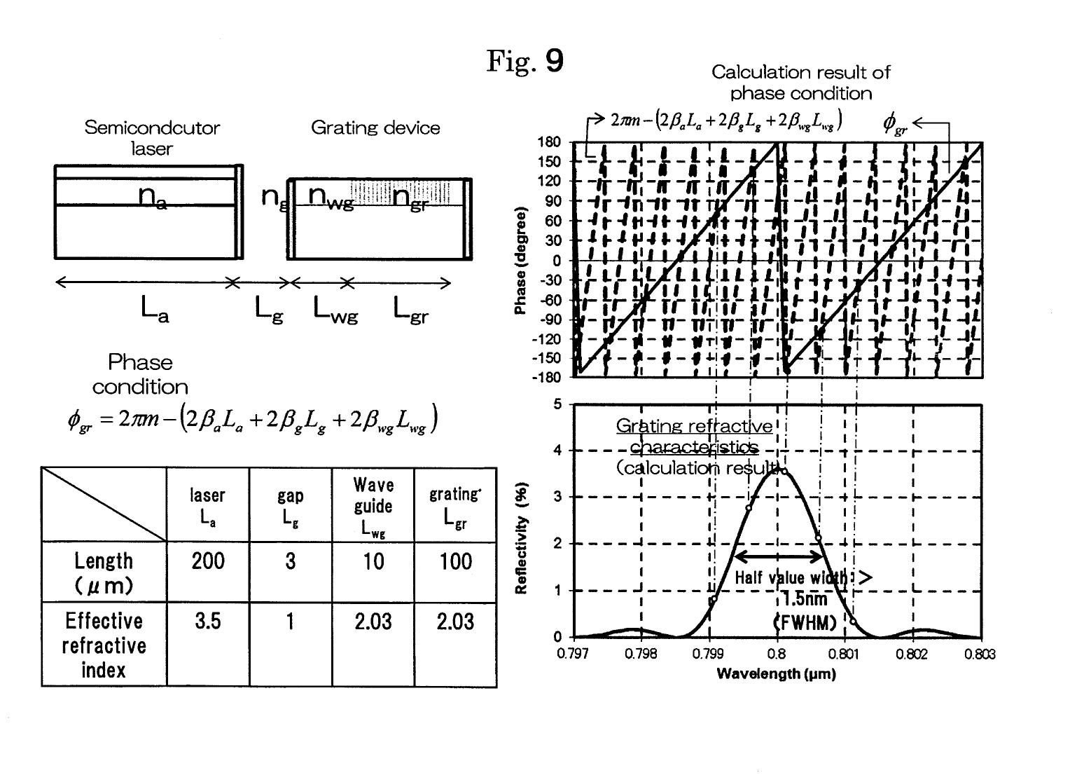

As illustrated in FIG. 11, the laser oscillation condition is determined by the gain condition and the phase condition. The wavelengths satisfying the phase condition are discrete as illustrated in, for example, FIG. 9. In particular, in the present structure, adjustment of the temperature coefficient of the the gain curve (0.3 nm/° C. in the case of GaAs) close to the temperature coefficient dλ_{G}/dT of the grating can maintain the laser oscillation wavelength within Δλ_{G}. In addition, when 2 or more and 5 or less longitudinal modes are present within Δλ_{G}, the laser oscillation wavelength repeatedly exhibits mode-hopping within Δλ_{G}, which can reduce the possibility of production of laser oscillation outside of Δλ_{G}. This allows operation at a stable wavelength and with a stable output power without causing large mode hops.

In a suitable embodiment, the active layer has a length Lₐ of 500 μm or less. In this regard, the active layer preferably has a length Lₐ of 300 μm or less. To enhance the laser output, the active layer more preferably has a length Lₐ of 150 μm or more.

$$\vert \frac{d {λ}_{G}}{d T} - \frac{d {λ}_{TM}}{d T} \vert ≦ 0.03 nm / ° C . \qquad ( 6 )$$

In the Formula (6), dλ_{G}/dT is the temperature coefficient of the Bragg wavelength.

dλ_{TM}/dT is the temperature coefficient of the wavelengths satisfying the phase condition of the external resonator type laser.

In the formula, λ_{TM} is a wavelength satisfying the phase condition of the external-resonator type laser, i.e., a wavelength satisfying the phase condition in the (Formula 2.3) described above. The wavelength is referred to as “longitudinal mode” in this specification.

Now, longitudinal modes will be described in detail.

In the Formula (2.3), β is equal to 2πneff/λ, wherein neff is the effective refractive index in the term, and λ satisfying this is λ_{TM}. φ2 is the phase change in the Bragg grating.

ΔG_{TM} is the spacing between the wavelengths satisfying the phase condition (longitudinal mode spacing) of the external resonator type laser. There are a plurality of λ_{TM}, and thus ΔG_{TM} is the difference between the plurality of λ_{TM}. Δλ described above is equal to ΔG_{TM} and λ_{S} is equal to λ_{TM}.

Thus, satisfaction of the Formula (6) results in increase in the temperature at which a mode hop occurs, which can actually prevent mode hops. The numerical value in the Formula (6) is more preferably 0.025 or less.

In a suitable embodiment, the grating device has a length L_{WG} of 600 μm or less. L_{WG} is preferably 400 μm or less and more preferably 300 μm or less. L_{WG} is preferably 50 μm or more.

The distance L_{g} between the light-emitting face of the light source and the incident face of the optical waveguide is preferably nearer to zero, on the viewpoint of improving the connection efficiency of the semiconductor laser and grating device. On the other hand, on the viewpoint of enabling the use in a wide temperature range, it is necessary to prevent the mechanical interference due to the thermal expansion. According to a preferred embodiment, the distance L_{g} between the emitting face of the light source and the incident face of the optical waveguide is made 1 μm or more and 10 μm or less. It is thus possible to perform stable oscillation. However, the incident-side propagating portion may not be provided.

### EXAMPLES

### Example 1

The system as illustrated in FIGS. 2, 5 and 6 was produced.

In particular, Ti film was formed on a z-plate of a lithium niobate crystal substrate doped with MgO, and a grating pattern was formed in a direction of y-axis by photolithography technique. Then, grating grooves having a pitch spacing Λ of 222 nm and a length L_{b} of 100 μm was formed using the Ti pattern as a mask by reactive ion etching with fluorine based gases. The grating had a groove depth td of 40 nm. To form an optical waveguide that causes light to propagate along the y-axis, dry etching was performed using a reactive ion etching (RIE) system to form ridge grooves.

Here, the width Wm of the optical waveguide and height Tr in the Bragg grating 12 were made 3 μm and 0.5 μm. At the same time, as shown in FIG. 2, it was provided the connecting portion 20a having a constant thickness, tapered portion 20b and emitting portion 20c having a constant thickness. The dimensions in the respective portions were as follows.

Width Wm of the optical waveguide in the connecting portion 20a: 3 μm
Height Tr of the optical waveguide in the connecting portion 20a: 0.5 μm
Width Wout of the optical waveguide in the emitting portion 20c: 1 μm
Height Tr of the optical waveguide in the emitting portion 20c: 0.5 μm
Width Wm of the optical waveguide in the tapered portion 20b: 1 to 3 μm
Height Tr of the optical waveguide in the tapered portion 20b: 0.5 μm

Further, the buffer layer 16 composed of SiO₂ was formed in 0.5 μm on the groove forming face by a sputtering system. A Black LN substrate was used as the supporting substrate to adhere the face with the grating formed thereon.

Then, the side of the black LN substrate of it was adhered on a surface plate, and the bottom face with the grating formed thereon of the LN substrate was subjected to precise polishing to decrease the thickness (Tₛ) to 1.2 μm. Thereafter, it was removed from the surface plate, and the buffer layer 17 of SiO₂ was formed in 0.5 μm on the polished face by sputtering.

Then, the resultant was cut into bars using a dicing device. The both end faces were optically polished, and then an AR coating having a reflectance of 0.1% was coated on the both end faces. Finally, the resultant was cut into chips to produce grating devices. The devices had a width of 1 mm and a length L_{wg} of 500 μm.

Then, with regard to the optical characteristics of the grating devices, the reflective characteristics were evaluated from the transmission characteristics by inputting light into the grating devices using a superluminescent diode (SLD), which is a broadband wavelength source, and analyzing the output light with an optical spectrum analyzer. As a result, at to TE mode, the central reflective wavelength was 975 nm, the maximum reflectance was 20 percent and the half value width Δλ_{G} was 2 nm.

It was mounted the laser module shown in FIG. 6. As the light source device, it was used a conventional GaAs series laser whose emitting side end face was not covered with an AR coating.

Specification of Light Source Device:

Center wavelength: 977 nm

### Output: 40 mW

Full width at half maximum: 0.1 nm
Length of laser device: 250 μm

### Mounting Specification:

### Lg: 1 μm

### Lm: 20 μm

After formation of the module, the semiconductor laser was operated using current control (ACC), without using a Peltier device and without using a photodiode for monitoring. As to the laser characteristics, the module exhibited a center wavelength of 975 nm corresponding to the reflection wavelength of the grating. Although the output power was lower than that in the case without the grating device, the output power was proved to be 30 mW.

The shape of the near field pattern at the emitting side end face of the grating device was of substantially true circle, of 1 μm in the horizontal direction and 1 μm in the vertical direction. Further, the single mode was maintained even in the case that the temperature was changed from 20° C. to 70° C.

### Comparative Example

In the Example 1, the width of the optical waveguide was made constant value of 3 μm and the height Tr was made constant value of 0.5 μm over the whole length of the optical waveguide 18. Thereafter, the grating device was produced according to the same procedure.

Then, with regard to the optical characteristics of the grating devices, the reflective characteristics were evaluated from the transmission characteristics by inputting light into the grating devices using a superluminescent diode (SLD), which is a broadband wavelength source, and analyzing the output light with an optical spectrum analyzer. As a result, at to TE mode, the central reflective wavelength was 975 nm, the maximum reflectance was 20 percent and the half value width Δλ_{G}was 2 nm.

Then, as shown in FIG. 6, the laser module was mounted. It was used a conventional GaAs series laser whose emitting-side end face is not covered with an AR coating, as the light source device.

Specification of Light Source Device:

Center wavelength: 977 nm

### Output: 40 mW

Full width at half maximum: 0.1 nm
Length of laser device: 250 μm

### Mounting Specification:

### Lg: 1 μm

### Lm: 20 μm

After formation of the module, the semiconductor laser was operated using current control (ACC), without using a Peltier device and without using a photodiode for monitoring. As to the laser characteristics, the module exhibited a center wavelength of 975 nm corresponding to the reflection wavelength of the grating. Although the output power was lower than that in the case without the grating device, the output power was proved to be 30 mW.

The shape of the near field pattern at the emitting side end face of the grating device was of compressed circle, of 3 μm in the horizontal direction, 1 μm in the vertical direction and an aspect ratio of 3. Further, multi-mode was excited around 70° C. in the case that the temperature was changed from 20° C. to 70° C.

1. An external resonator type light emitting system comprising a semiconductor light source and a grating device constituting an external resonator with said semiconductor light source:
wherein said semiconductor light source comprises an active layer oscillating a semiconductor light;
wherein said grating device comprises a ridge type optical waveguide comprising an incident face to which said semiconductor laser light is made incident and an emitting face for emitting an emitted light having a desired wavelength, a Bragg grating comprising convexes and concaves and formed in said ridge type optical waveguide, and an emitting side propagating portion disposed between said incident face and said Bragg grating;
wherein said system performs laser oscillation in a reflection wavelength range of said Bragg grating; and
wherein a width of said optical waveguide in said Bragg grating and a width of said optical waveguide at said emitting face are different from each other.

2. The system of claim 1, wherein said width of said optical waveguide at said emitting face is smaller than said width of said optical waveguide in said Bragg grating.

3. The system of claim 1, wherein said emitting side propagating portion comprises a tapered portion, and wherein a width of said optical waveguide is decreased from said Bragg grating to said emitting face in said tapered portion.

4. The system of claim 1, wherein said grating device comprises a supporting substrate and an optical material layer provided on said supporting substrate and having a thickness of 0.5 μm or larger and 3.0 μm or smaller.

5. The system of claim 1, wherein a material forming said Bragg grating is selected from the group consisting of gallium arsenide, lithium niobate, tantalum oxide, zinc oxide, aluminum oxide and lithium tantalate.

6. The system of claim 1, wherein relationships of the following formulas (1) and (2) are satisfied.
10 μm≦L_{b}≦300 μm (1)
20 nm≦td≦250 nm (2)
wherein L_{b} in the Formula (1) is a length of said Bragg grating, and
wherein td in the Formula (2) is a depth of said convexes and concaves constituting said Bragg grating.

7. The system of claim 1, wherein relationships of the following formulas (3) and (4) are satisfied.
0.8 nm≦Δλ_{G}≦6.0 nm (3)
n_{b}≧1.8 (4)
wherein Δλ_{G} in the Formula (3) is a full width at half maximum of a peak Bragg reflectance, and
wherein n_{b} in the Formula (4) is a refractive index of a material constituting said Bragg grating.

8. The system of claim 1, wherein relationship represented by the following Formula (5) is satisfied:
L_{WG}≦500 μm (5)
wherein L_{WG} in the formula (5) is a length of said grating device.

9. The system of claim 7, wherein 2 or more and 5 or less wavelengths satisfying phase condition for laser oscillation exist within said full width at half maximum Δλ_{G}.

10. The system of claim 1, wherein relationship of the following formula (6) is satisfied.
$$\vert \frac{d {λ}_{G}}{d T} - \frac{d {λ}_{TM}}{d T} \vert ≦ 0.03 nm / ° C . \qquad ( 6 )$$
wherein dλ_{G}/dT in the formula (6) is a temperature coefficient of a Bragg wavelength, and
wherein dλ_{TM}/dT is a temperature coefficient of a wavelength satisfying phase matching condition of an external resonator laser.
